(19) United States
(12) Patent Application Publication
(10) Pub. No.: US 2020/0412089 A1
(43) Pub. Date: Dec. 31, 2020

(54) SURFACE EMITTING LASER

(71) Applicant: SUMITOMO ELECTRIC INDUSTRIES, LTD., Osaka (JP)

(72) Inventors: Natsumi MORI, Osaka (JP); Hiroyuki YOSHINAGA, Osaka (JP)

(21) Appl. No.: 16/877,952

(22) Filed: May 19, 2020

(30) Foreign Application Priority Data
Jun. 28, 2019 (JP) 2019-122050

(51) Int. Cl. H01S 5/042; H01S 5/183; H01S 5/343

(52) U.S. Cl. CPC H01S 5/04256; H01S 5/18372; H01S 5/34313; H01S 5/18313; H01S 5/18347

(57) ABSTRACT

A surface emitting laser includes a substrate, semiconductor layers on the substrate, a light transmitting window configured to transmit laser light from the semiconductor layers, a first electrode pad, a second electrode pad, a first dummy pad, and a second dummy pad, wherein the first electrode pad, the second electrode pad, the first dummy pad, and the second dummy pad are disposed on the semiconductor layers at a place different from the light transmitting window, and wherein the substrate is classified into first through fourth regions by a straight line extending in a first direction and a straight line extending in a second direction perpendicular to the first direction, the first electrode pad being situated in the first region, the second electrode pad being situated in the second region, the first dummy pad being situated in the third region, and the second dummy pad being situated in the fourth region.

### BACKGROUND OF THE INVENTION

### 1. Field of the Invention

The disclosures herein relate to a surface emitting laser.

### 2. Description of the Related Art

A vertical cavity surface emitting laser (VCSEL), which is also referred to as a surface emitting laser, has two reflector layers and an active layer interposed between the reflector layers disposed over a semiconductor substrate, and emits light in the direction perpendicular to the surface of the semiconductor substrate. A surface emitting laser has a current confinement structure that is made by forming a mesa with the active layer and the reflector layers and by selectively oxidizing a portion of the reflector layers of the mesa to form an oxide layer (see Patent Document 1, for example).

The surface emitting laser as described above is made by processing the surface of a semiconductor substrate. Such a surface has a mesa and electrode pads formed thereon, so that the top surface of a surface emitting laser chip has surface irregularities. In the case in which the elevation of the top surface varies from position to position on a surface emitting laser chip, the surface emitting laser chip may be inclined when held by a collet for transfer. As a result, the portion for transmitting laser light may be damaged, or transfer may not be completed as desired.

Accordingly, there may be a need for a surface emitting laser that is not inclined when held by a collet at the time of transferring the surface emitting laser.

### Related-Art Documents

[Patent Document 1] Japanese Laid-open Patent Publication No. 2019-33210

### SUMMARY OF THE INVENTION

According to an embodiment, a surface emitting laser includes a substrate, semiconductor layers including a lower contact layer, a lower reflector layer, an active layer, an upper reflector layer, and an upper contact layer which are laminated, in the order named, on the substrate, a light transmitting window configured to transmit laser light from the semiconductor layers, a first electrode pad connected to the upper contact layer, a second electrode pad connected to the lower contact layer, a first dummy pad, and a second dummy pad, wherein the first electrode pad, the second electrode pad, the first dummy pad, and the second dummy pad are disposed on the semiconductor layers at a place different from the light transmitting window, and wherein the substrate is classified into a first region, a second region, a third region, and a fourth region by both a straight line extending in a first direction passing through a center of the substrate in a plan view and a straight line extending in a second direction perpendicular to the first direction and passing through the center of the substrate, the first electrode pad being situated in the first region, the second electrode pad being situated in the second region, the first dummy pad being situated in the third region, and the second dummy pad being situated in the fourth region.

According to the present disclosures, a surface emitting laser is prevented from being inclined when held by a collet at the time of transferring the surface emitting laser.

Other objects and further features of the present invention will be apparent from the following detailed description when read in conjunction with the accompanying drawings.

### BRIEF DESCRIPTION OF THE DRAWINGS

FIG. 1 is a top view of a surface emitting laser chip;

FIG. 2 is a schematic cross-sectional view of the surface emitting laser;

FIG. 3 is an illustrative drawing showing the transfer of the surface emitting laser chip;

FIG. 4 is an illustrative drawing showing the contact surface between the surface emitting laser chip and a collet;

FIG. 5 is a top view of a surface emitting laser chip according to an embodiment of the present disclosures;

FIG. 6 is a schematic cross-sectional view of the surface emitting laser according to the embodiment of the present disclosures;

FIG. 7 is an illustrative drawing showing the transfer of the surface emitting laser chip according to the embodiment of the present disclosures;

FIG. 8 is an illustrative drawing showing the contact surface between the collet and the surface emitting laser chip of the embodiment of the present disclosures;

FIG. 9 is an illustrative drawing showing a first dummy pad of the surface emitting laser according to the embodiment of the present disclosures;

FIG. 10 is an illustrative drawing showing the contact surface between another collet and the surface emitting laser chip of the embodiment of the present disclosures;

FIG. 11 is a cross-sectional view of a surface emitting laser according to the embodiment of the present disclosures;

FIG. 12 is an illustrative drawing showing a first variation of the first dummy pad of the surface emitting laser according to the embodiment of the present disclosures;

FIG. 13 is an illustrative drawing showing a second variation of the first dummy pad of the surface emitting laser according to the embodiment of the present disclosures; and

FIG. 14 is an illustrative drawing showing a third variation of the first dummy pad of the surface emitting laser according to the embodiment of the present disclosures.

### DESCRIPTION OF THE PREFERRED EMBODIMENTS

Embodiments will be described in the following.

### Description of Embodiments of the Present Disclosures

Embodiments of the present disclosures will be listed and described first. In the following description, the same or corresponding elements are referred to by the same reference numerals, and a duplicate description thereof will be omitted.

[1] According to an embodiment of the present disclosures, a surface emitting laser includes a substrate, semiconductor layers including a lower contact layer, a lower reflector layer, an active layer, an upper reflector layer, and an upper contact layer which are laminated, in the order named, on the substrate, a light transmitting window configured to transmit laser light from the semiconductor layers, a first electrode pad connected to the upper contact layer, a second electrode pad connected to the lower contact layer, a first dummy pad, and a second dummy pad, wherein the first electrode pad, the second electrode pad, the first dummy pad, and the second dummy pad are disposed on the semiconductor layers at a place different from the light transmitting window, wherein the substrate is classified into a first region, a second region, a third region, and a fourth region by both a straight line extending in a first direction passing through a center of the substrate in a plan view and a straight line extending in a second direction perpendicular to the first direction and passing through the center of the substrate, the first electrode pad being situated in the first region, the second electrode pad being situated in the second region, the first dummy pad being situated in the third region, and the second dummy pad being situated in the fourth region.

This arrangement prevents a surface emitting laser from being inclined when held by a collet at the time of transferring the surface emitting laser.

[2] A surface emitting laser includes a substrate, semiconductor layers including a lower contact layer, a lower reflector layer, an active layer, an upper reflector layer, and an upper contact layer which are laminated, in the order named, on the substrate, a light transmitting window configured to transmit laser light from the semiconductor layers, a first electrode pad connected to the upper contact layer, a second electrode pad connected to the lower contact layer, a first dummy pad, and a second dummy pad, wherein the first electrode pad, the second electrode pad, the first dummy pad, and the second dummy pad are disposed on the semiconductor layers at a place different from the light transmitting window, and wherein the light transmitting window is situated between the first dummy pad and the second dummy pad.

This arrangement prevents a surface emitting laser from being inclined when held by a collet at the time of transferring the surface emitting laser.

[3] The first dummy pad and the second dummy pad are an oblong rectangular shape, wherein a length of a short side of the oblong rectangular shape is greater than or equal to 5 micrometers and smaller than or equal to 40 micrometers, and wherein a length of a long side of the oblong rectangular shape is greater than or equal to 80 micrometers and smaller than or equal to 100 micrometers.

This arrangement allows the first dummy pad and the second dummy pad to come in contact with the hold face of a collet, thereby preventing a surface emitting laser from being inclined when held by the collet.

[4] A plurality of the noted first dummy pads are provided, wherein a length of the first dummy pad in the first direction ranges from 20 micrometers to 40 micrometers, and wherein the plurality of first dummy pads are aligned in the second direction perpendicular to the first direction.

This arrangement prevents a surface emitting laser from being inclined when held by a collet.

[5] A distance from an edge of the substrate to the edge of the first dummy pad that is closest to the edge of the substrate is greater than or equal to 20 micrometers and less than or equal to 50 micrometers.

This arrangement prevents a surface emitting laser from being inclined when held by a collet.

### Details of Embodiments of the Present Disclosures

In the following, an embodiment of the present disclosures will be described in detail, but the present embodiments are not limited to those disclosed herein. In the present application, the X1-X2 direction, the Y1-Y2 direction, and the Z1-Z2 direction are orthogonal to each other. The plane that includes the X1-X2 direction and the Y1-Y2 direction is referred to as an XY plane. The plane that includes the Y1-Y2 direction and the Z1-Z2 direction is referred to as a YZ plane. The plane that includes the Z1-Z2 direction and the X1-X2 direction is referred to as a ZX plane.

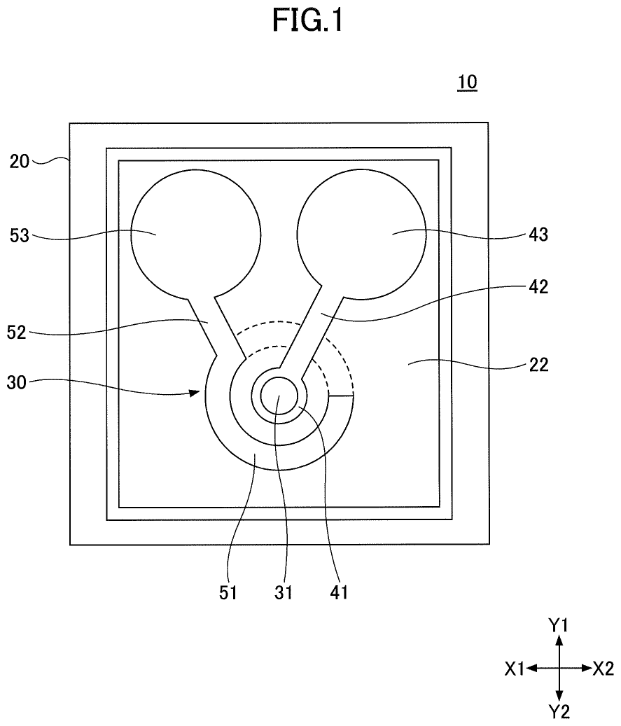

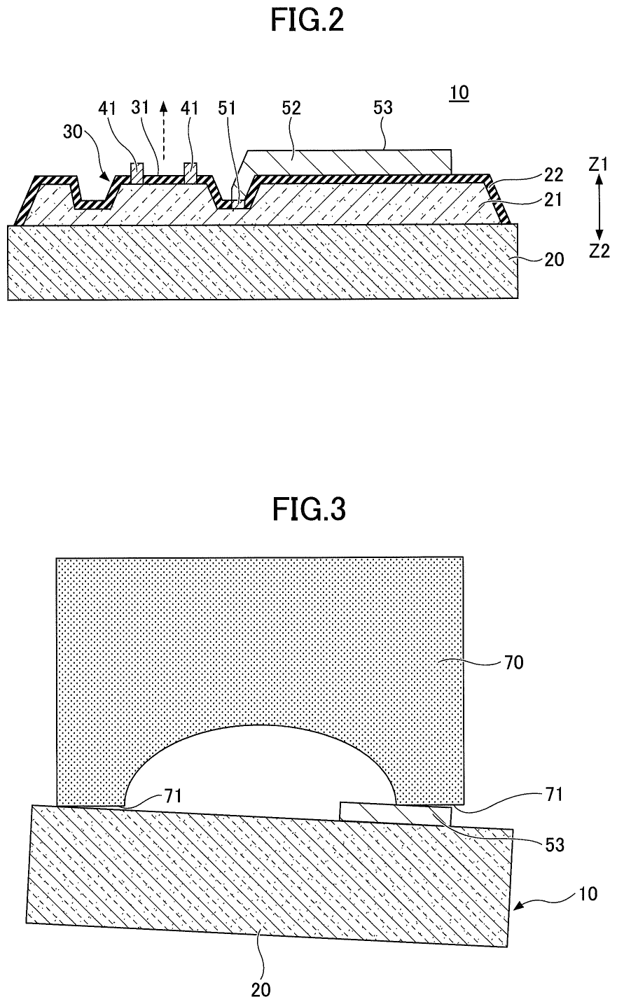

A surface emitting laser that is inclined when held by a collet at the time of transferring the surface emitting laser will first be described by referring to a surface emitting laser chip 10 illustrated in FIG. 1 ad FIG. 2. FIG. 1 is a top view of the surface emitting laser chip 10, and FIG. 2 is a cross-sectional view of the surface emitting laser chip 10 that is schematically illustrated for the sake of convenience.

The surface emitting laser chip 10 has semiconductor layers 21 formed on a substrate 20 made of GaAs. A mesa 30 comprised of the semiconductor layers 21 is formed by processing the semiconductor layers 21. An insulating film 22 is formed on the semiconductor layers 21, on the lateral surface of the mesa 30, and the like. A lower DBR layer, an active layer, and an upper DBR layer (now shown) are formed in the mesa 30. A p electrode 41 having a ring shape is formed around the light transmitting window 31 on the upper surface of the mesa 30. An n electrode 51 having an arc shape is formed around the mesa 30. The surface emitting laser receives current that flows between the p electrode 41 and the n electrode 51, thereby emitting laser light from the light transmitting window 31 situated on the top surface of the mesa 30 in the direction perpendicular to the surface of the substrate 20, as illustrated by a dashed-line arrow.

The p electrode 41 is connected to a p electrode pad 43 via an interconnect 42, and the n electrode 51 is connected to an n electrode pad 53 via an interconnect 52. The p electrode pad 43 and the n electrode pad 53 are used for wire bonding connections or the like, and, thus, are required to have a suitable size. Their thickness is set to 1.7 micrometers.

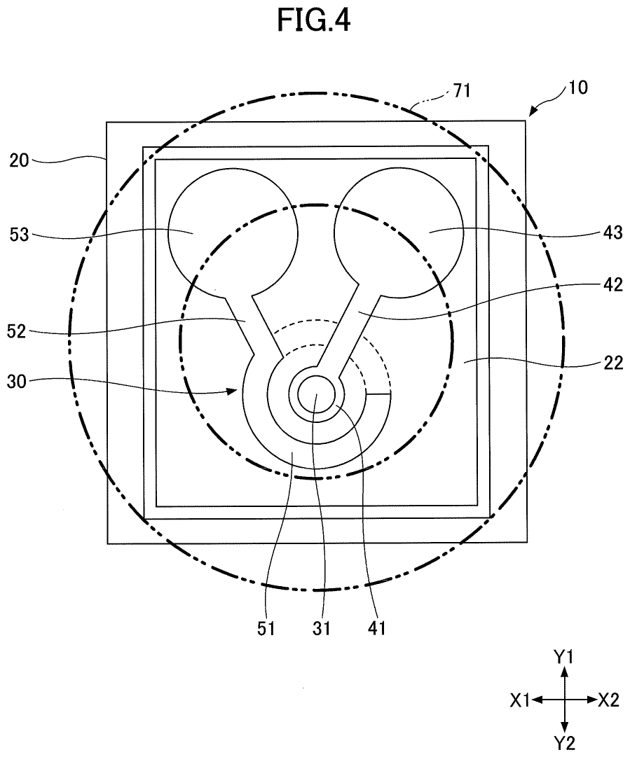

In the example illustrated in FIG. 2, the surface emitting laser chip 10 as described above has a lower height on the left side where the n electrode pad 53 or the like is not provided than on the right side where the n electrode pad 53 is provided. Because of this, when the surface emitting laser chip 10 is held by a collet 70 for transfer, the surface emitting laser chip 10 is held in an inclined position relative to the contact surface 71 of the collet 70, as shown in FIG. 3. In this case, a positional displacement of the surface emitting laser chip 10 with respect to the contact surface 71 of the collet 70 may occur, and may cause damage to the light transmitting window 31 situated on the top surface of the surface emitting laser chip 10, or may results in a failure to transfer the surface emitting laser chip 10 properly. FIG. 4 illustrates the case in which the collet 70 for transferring the surface emitting laser chip 10 is a round collet, so that the contact surface 71 of the collet 70 corresponds to the area between the inner circle and the outer circle shown in the double-dotted-and-dashed lines. In FIG. 3, the structural details of the surface emitting laser chip 10 are not illustrated for the sake of convenience.

Accordingly, there is a need for a surface emitting laser that is not inclined when held by a collet at the time of transferring the surface emitting laser chip.

### Surface Emitting Laser

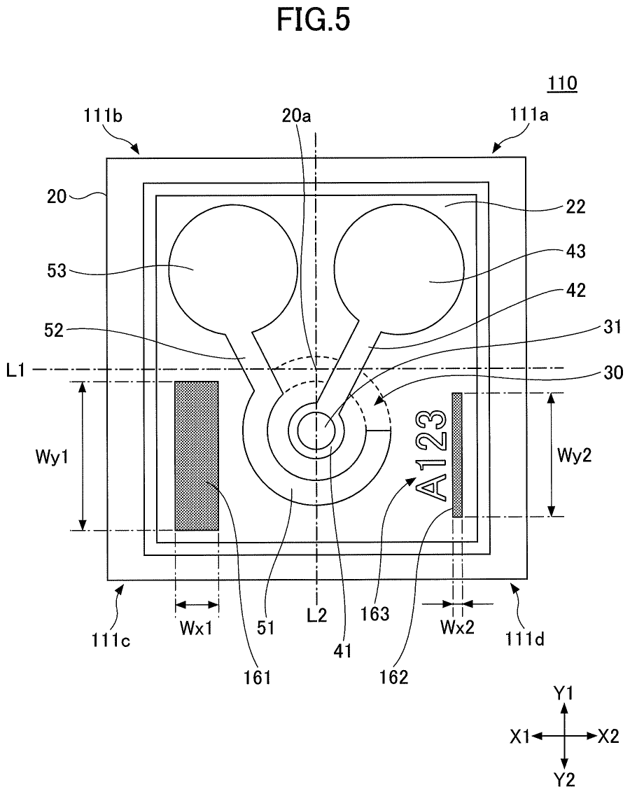

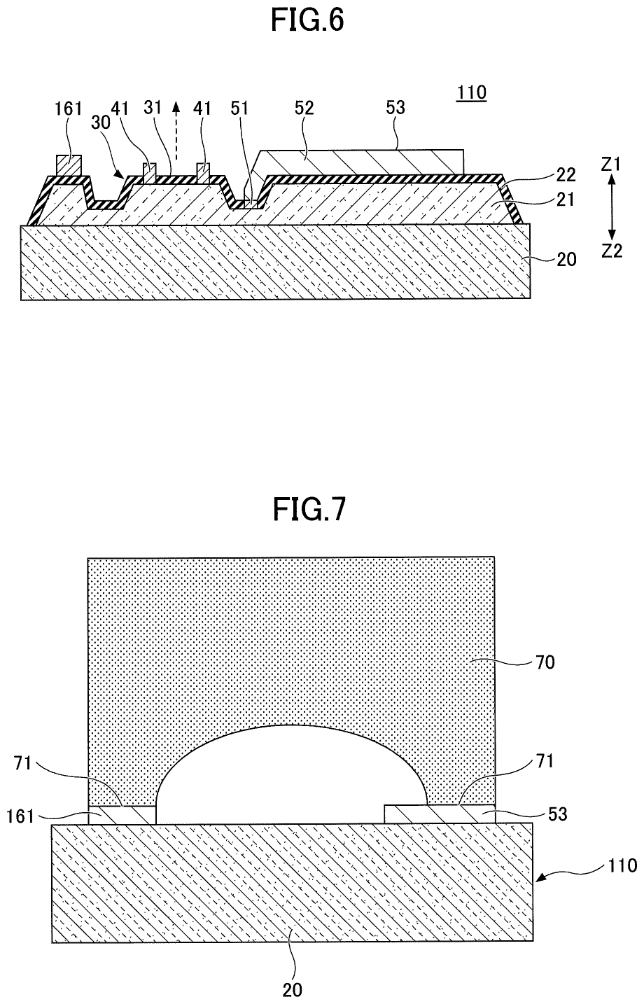

In the following, a surface emitting laser according to the present embodiment will be described with reference to FIG. 5 and FIG. 6. FIG. 5 is a top view of a surface emitting laser chip 110 of the present embodiment, and FIG. 6 is a cross-sectional view of the surface emitting laser chip 110 that is schematically illustrated for the sake of convenience.

The surface emitting laser chip 110 of the present embodiment has semiconductor layers 21 formed on a substrate 20 made of GaAs. A mesa 30 comprised of the semiconductor layers 21 is formed by processing the semiconductor layers 21. The semiconductor layers 21 are comprised of a first lower DBR layer, a lower contact layer, a second lower DBR layer, an active layer, an upper DBR layer, and an upper contact layer formed on the substrate 20, as will be described later. In the present application, the second lower DBR layer or a set of the first lower DBR layer and the second lower DBR layer is referred to as a lower reflector layer, and the upper DBR layer is referred to as an upper reflector layer.

An insulating film 22 is formed on the semiconductor layers 21, on the lateral surface of the mesa 30, and the like. The lower DBR layer, the active layer, and the upper DBR layer (not shown in FIG. 6) are included in the mesa 30. A p electrode 41 having a ring shape is formed around the light transmitting window 31 on the upper surface of the mesa 30. An n electrode 51 having an arc shape is formed around the mesa 30. The surface emitting laser receives current that flows between the p electrode 41 and the n electrode 51, thereby emitting laser light from the light transmitting window 31 situated on the top surface of the mesa 30 in the direction perpendicular to the surface of the substrate 20, as illustrated by a dashed-line arrow.

The p electrode 41 is connected to a p electrode pad 43 via an interconnect 42, and the n electrode 51 is connected to an n electrode pad 53 via an interconnect 52. A groove is formed around the mesa 30. The semiconductor layers 21 situated outside the groove are referred to as a terrace of the semiconductor layers 21. The p electrode pad 43 and the n electrode pad 53 are formed on the terrace. The p electrode pad 43 and the n electrode pad 53 are used for wire bonding connections or the like, and, thus, are required to have a suitable size. For example, they are a circular shape with a diameter of 100 micrometers, and has a height of 1 to 4 micrometers above the upper surface of the terrace of the semiconductor layers 21, which is more preferably in the range of 1.4 micrometers to 1.7 micrometers. In the present application, the p electrode pad 43 may sometimes be referred to as a first electrode pad, and the n electrode pad 53 may sometimes be referred to as a second electrode pad.

The surface emitting laser of the present embodiment has a first dummy pad 161 and a second dummy pad 162. The first dummy pad 161 and the second dummy pad 162 have a height, above the upper surface of the terrace of the semiconductor layers 21, which is in the range of 1 to 4 micrometers and preferably in the range of 1.4 to 1.7 micrometers, and are substantially the same thickness as the p electrode pad 43, the n electrode pad 53, and the like.

The p electrode pad 43, the n electrode pad 53, the first dummy pad 161, and the second dummy pad 162 are formed on the insulating film on the semiconductor layers 21 at a different place from the light transmitting window 31.

The height of the upper surface of the p electrode pad 43 above the upper surface of the terrace semiconductor layers 21 is at least 0.5 micrometers higher than the height of the upper surface of the p electrode 41. Similarly, the height of the upper surface of the n electrode pad 53, the first dummy pad 161, and the second dummy pad 162 with reference to the upper surface of the terrace semiconductor layers 21 is at least 0.5 micrometers higher than the height of the upper surface of the p electrode 41. Making the upper surfaces of the electrode pads and the dummy pads higher than the p electrode 41 may prevent the light transmitting window 31 and the p electrode 41 from coming in contact with a collet when the surface emitting laser is held by the collet. Preventing such a contact serves to prevent damage to the light transmitting window 31 and to the p electrode 41.

Differences in height between the upper surfaces of the p electrode pad 43, the n electrode pad 53, the first dummy pad 161, and the second dummy pad 162 are preferably less than or equal to 3 micrometers. This arrangement allows the first dummy pad 161 and the second dummy pad 162 to come in contact with the hold face of a collet, thereby preventing a surface emitting laser from being inclined when held by the collet. The first dummy pad 161 and the second dummy pad 162 are preferably a metal layer having a thickness of 1 micrometer or more formed on the insulating film 22. This arrangement prevents an impact caused by the collet coming in contact with the dummy pads from causing damage to the insulating film 22.

The substrate 20 serving as a basis for the surface emitting laser chip 110 of the present embodiment is a square or oblong rectangular shape.

The substrate 20 serving as a basis for the surface emitting laser chip 110 may be a square with a side of 200 micrometers to 300 micrometers, for example. As illustrated in FIG. 5, the substrate 20 may be classified into four regions by both a straight line L1 passing through the center 20a of the substrate 20 in a plan view and a straight line L2 perpendicular to the straight line L1 and passing through the center 20a of the substrate 20. The straight line L1 extends in the X1-X2 direction, and the straight line L2 extends in the Y1-Y2 direction. In the present application, the X1-X2 direction may be referred to as the first direction, and the Y1-Y2 direction may be referred to as the second direction. In some cases, the straight line L1 is referred to as a first-direction straight line, and the straight line L2 is referred to as a second-direction straight line.

The top right region among the four classified regions is referred to as a first region 111a. The remaining regions are referred to as a second region 111b, a third region 111c, and a fourth region 111d in this order in a counterclockwise direction. In the present embodiment, the p electrode pad 43 is disposed in the first region 111a on the surface of the surface emitting laser chip 110, and the n electrode pad 53 is disposed in the second region 111b. The first dummy pad 161 is disposed in the third region 111c, and the second dummy pad 162 is disposed in the fourth region 111d. The term “plan view” refers to a view that is taken from above the substrate 20 or the surface emitting laser chip 110.

The mesa 30 and the light transmitting window 31 are positioned between the third region 111c and the fourth region 111d, so that the mesa 30 and the light transmitting window 31 are situated between the first dummy pad 161 and the second dummy pad 162. The first dummy pad 161 and the second dummy pad 162 are formed such that the Y1-Y2 direction coincides with the lengthwise direction, and the X1-X2 direction coincides with the widthwise direction.

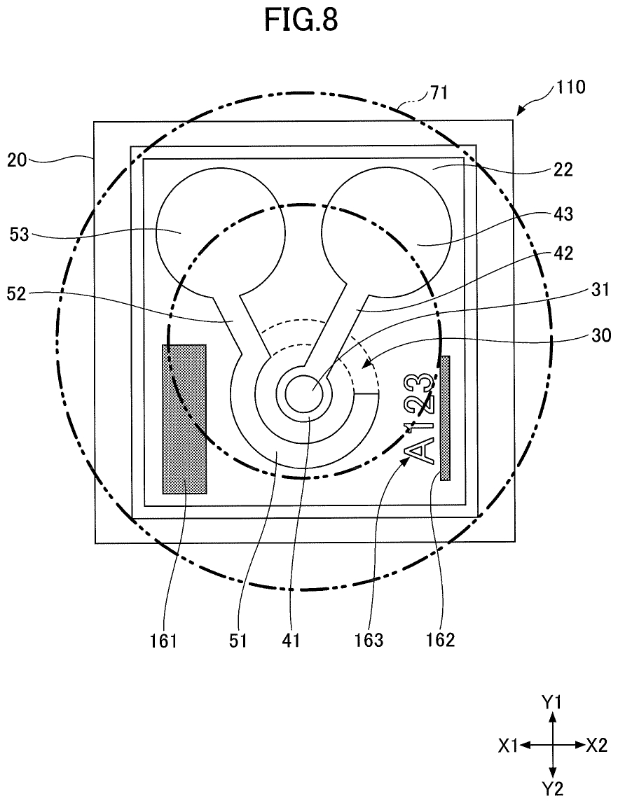

In the example illustrated in FIG. 6, the surface emitting laser chip 110 of the present embodiment has the n electrode pad 53 on the right-hand side, and has the first dummy pad 161 on the left-hand side which is approximately the same height as the n electrode pad 53. Because of this, when the surface emitting laser chip 110 is held by the collet 70 for transfer, the surface emitting laser chip 110 is properly held without being inclined relative to the contact surface 71 of the collet 70, as illustrated in FIG. 7. Accordingly, the surface emitting laser chip 110 can properly be transferred, without causing the contact surface 71 of the collet 70 to damage the light transmitting window 31 situated on the top surface of the surface emitting laser chip 110. In FIG. 7, the structural details of the surface emitting laser chip 110 of the present embodiment are not illustrated for the sake of convenience. FIG. 8 illustrates the case in which the collet 70 used for transferring the surface emitting laser chip 110 of the present embodiment is a round collet, so that the contact surface 71 of the collet 70 corresponds to the area between the inner circle and the outer circle shown in the double-dotted-and-dashed lines. The contact surface 71 of the round collet illustrated in FIG. 8 has an inner circle with a diameter of 50 micrometers to 100 micrometers and an outer circle with a diameter of 280 micrometers to 330 micrometers.

As illustrated in FIG. 8, more than half of the entire area of the first dummy pad 161 is in contact with the contact surface 71, and the entire area of the second dummy pad 162 is in contact with the contact surface 71. The second dummy pad 162 also has the function to allow the orientation of a chip number 163 to be identified, and is formed along the underside of the chip number 163.

As illustrated in FIG. 5, the first dummy pad 161 is an oblong rectangular shape having a width Wx1 of approximately 20 micrometers in the X1-X2 direction and a width Wy1 of approximately 100 micrometers in the Y1-Y2 direction. The second dummy pad 162 is an oblong rectangular shape having a width Wx2 of approximately 5 micrometers in the X1-X2 direction and a width Wy2 of approximately 80 micrometers in the Y1-Y2 direction.

In the present embodiment, the width Wx1 and the width Wx2, which are the short sides of oblong rectangles, are preferably greater than or equal to 5 micrometers and less than or equal to 40 micrometers. Excessively narrow widths Wx1 and Wx2 may cause the first dummy pad 161 and the second dummy pad 162 to be damaged upon coming in contact with the collet 70. Further, the mesa 30 is present on the X2 side of the first dummy pad 161 and on the X1 side of the second dummy pad 162, so that there is a limit to the extent to which the widths are increased.

The width Wy1 and the width Wy2, which are the long sides of oblong rectangles, are preferably greater than or equal to 80 micrometers and less than or equal to 100 micrometers. Excessively narrow widths Wy1 and Wy2 may cause the collect to fail to come in proper contact with the dummy pads when the position of the collet for holding is misaligned. Further, the n electrode pad 53 is present on the Y1 side of the first dummy pad 161, and the p electrode pad 43 is present on the Y1 side of the second dummy pad 162, so that there is a limit to the extent to which the widths are increased.

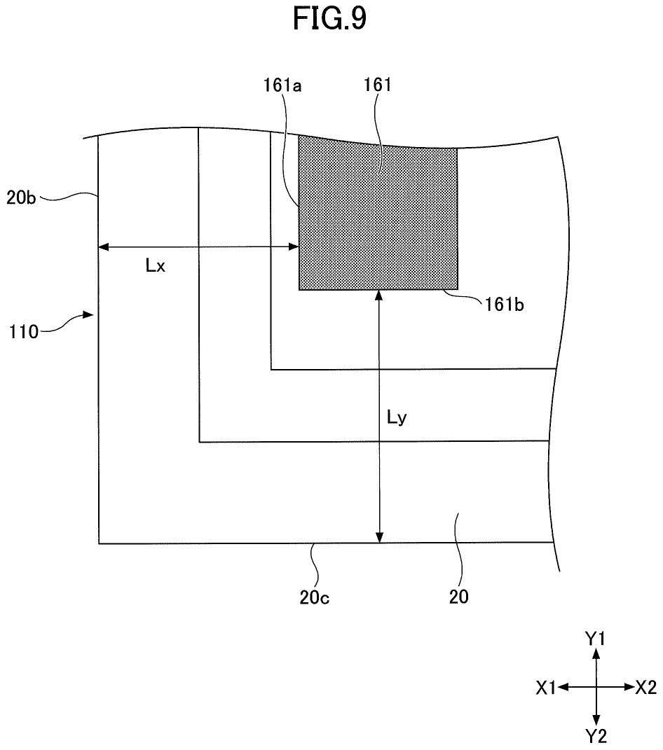

In the present embodiment, as illustrated in FIG. 9, the distance from an edge of the substrate 20, which is the edge of the surface emitting laser chip 110, to the edge of the first dummy pad 161 that is closest to the edge of the substrate 20 is greater than or equal to 20 micrometers and less than or equal to 50 micrometers. Specifically, the length Lx from the X1-side edge 20b of the substrate 20 to the X1-side edge 161a of the first dummy pad 161 is greater than or equal to 20 micrometers and less than or equal to 50 micrometers. The length Ly from the Y2-side edge 20c of the substrate 20 to the Y2-side edge 161b of the first dummy pad 161 is greater than or equal to micrometers and less than or equal to 50 micrometers. Excessively short lengths Lx and Ly may increase the likelihood of having defects such as the detachment of an insulating film during the cleavage process or the process of dicing a chip into pieces. Excessively long lengths Lx and Ly may decrease the contact area between the first dummy pad 161 or the like and the contact surface 71 of the collet 70, which may cause the surface emitting laser chip 110 to be held in an instable manner.

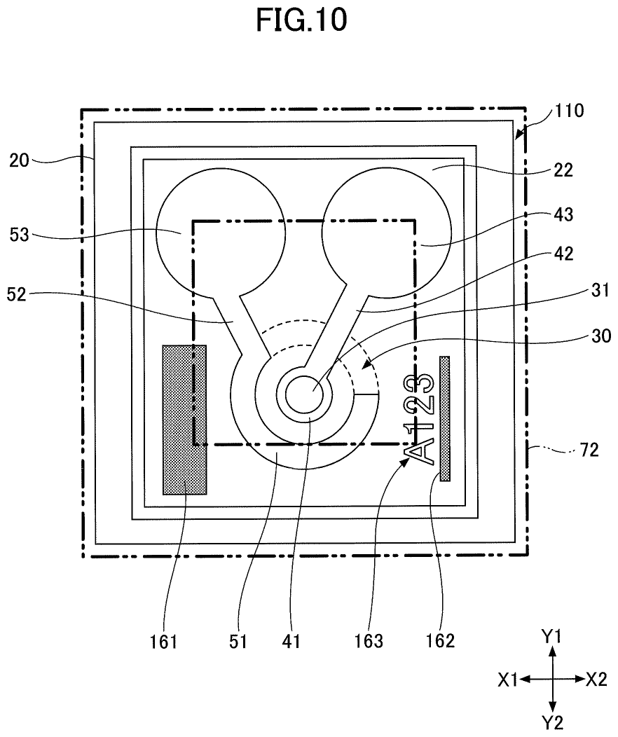

FIG. 10 illustrates the case in which the collet 70 used for transferring the surface emitting laser chip 110 of the present embodiment is a rectangular collet, so that the contact surface 72 of the rectangular collet corresponds to the area between the inner square and the outer square shown in the double-dotted-and-dashed lines. In this manner, the surface emitting laser of the present embodiment is also applicable to a rectangular collect. The contact surface 72 of the rectangular collet has an inner square with a side of 50 micrometers to 100 micrometers and an outer square with a side of 280 micrometers to 330 micrometers.

### Structural Details of Surface Emitting Laser

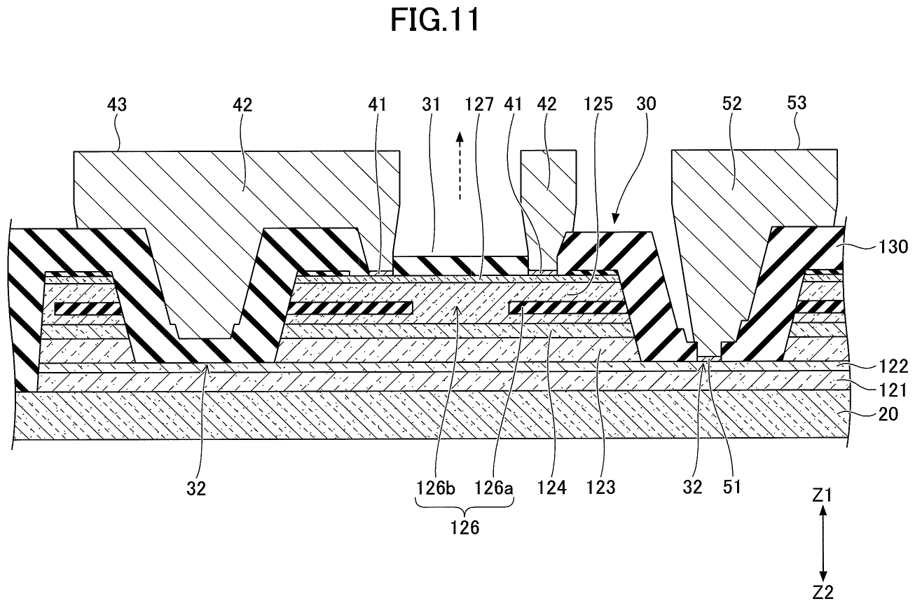

In the following, the structural details of the surface emitting laser according to the present embodiment will be described. FIG. 11 is a cross-sectional view of the surface emitting laser according to the present embodiment. The surface emitting laser of the present embodiment is such that a first lower DBR (distributed Bragg reflector) layer 121, a lower contact layer 122, a second lower DBR layer 123, an active layer 124, an upper DBR layer 125, and an upper contact layer 127 are formed in the order named on the substrate 20. It may be noted that, in the surface emitting laser of the present embodiment, the first lower DBR layer 121, the lower contact layer 122, the second lower DBR layer 123, the active layer 124, the upper DBR layer 125, and the upper contact layer 127 constitute the semiconductor layers 21 illustrated in FIG. 6.

The upper DBR layer 125 has an oxidized region 126a that is made by oxidizing part of the layers constituting the upper DBR layer 125. Upon the formation of the oxidized region 126a, the unoxidized region serves as an aperture region 126b. Accordingly, the surface emitting laser has a current confinement structure 126 comprised of the oxidized region 126a and the aperture region 126b. The oxidized region 126a is made by oxidizing a mesa 30 from the perimeter thereof. The oxidized region 126a contains aluminum oxide (Al₂O₃), for example, and has an insulating property, thereby conducting less current than the aperture region 126b. The aperture region 126b, which more readily conducts current than the oxidized region 126a, thus serves as a current path. Use of the current confinement structure 126 as described above allows current to be efficiently injected. In the present embodiment, the diameter of the aperture region 126b is 7.5 μm, for example.

The substrate 20 may be a semiconductor substrate made of gallium arsenide (GaAs) having a semi-insulating property, for example. A buffer layer made of GaAs and AlGaAs may be disposed between the substrate 20 and the first lower DBR layer 121.

The first lower DBR layer 121, the second lower DBR layer 123, and the upper DBR layer 125 are a multilayer semiconductor film in which AlₓGa₁₋ₓAs (x=0.90) and Al_{y}Ga_{1-y}As (y=0.1) with an optical film thickness of λ/4 are alternately laminated. The first lower DBR layer 121 is an i-type semiconductor layer with no dopant impurities. The second lower DBR layer 123 is an n-type semiconductor layer, which is doped with silicon (Si) serving as an impurity at a concentration of 7×10¹⁷ cm⁻³ or more and 4×10¹⁸ cm⁻³ or less, for example. The upper DBR layer 125 is a p-type semiconductor layer, which is doped with zinc (Zn) serving as an impurity at a concentration of 1×10¹⁸ cm⁻³ or more and 2×10¹⁹ cm⁻³ or less, for example.

The lower contact layer 122 is approximately 500 nm in thickness and made of n-type AlₓGa₁₋ₓAs (x=0.1) that is doped with Si serving as an impurity at a concentration of 2×10¹⁸ cm⁻³, for example. The upper contact layer 127 is approximately 200 nm in thickness and made of p-type (x=0.16) that is doped with Zn serving as an impurity at a concentration of 1×10¹⁹ cm⁻³, for example.

The active layer 124 has a multiple quantum well (MQW) structure in which In_{y}Ga_{1-y}As (y=0.107) layers and AlₓGa₁₋ₓAs (x=0.3) layers are alternately laminated, for example, providing an optical gain. It may be noted that the substrate 20, the first lower DBR layer 121, the lower contact layer 122, the second lower DBR layer 123, the active layer 124, the upper DBR layer 125, and the upper contact layer 127 may be made of different compound semiconductors from those noted above.

The mesa 30 is constituted by the second lower DBR layer 123, the active layer 124, the upper DBR layer 125, and the upper contact layer 127. Specifically, the second lower DBR layer 123, the active layer 124, the upper DBR layer 125, and the upper contact layer 127 are removed around the area for erecting the mesa 30 to form a groove 32, thereby forming the mesa 30 constituted by the semiconductor layers. The height of the mesa 30 is greater than or equal to 4.5 μm and less than or equal to 5.0 μm, for example. The width of the top face is 30 μm, for example. The width of the groove 32 is 20 micrometers, for example. The mesa 30 has the active layer 124, the upper DBR layer 125, and the upper contact layer 127 at the center thereof.

An insulating film 130 is formed on the semiconductor layers at the places including the upper surface and lateral surface of the mesa 30. The insulating film 130 is made of silicon nitride (SiN), silicon oxynitride (SiON), or the like.

A p electrode 41 is formed on the upper contact layer 127 at the top of the mesa 30. An n electrode 51 is formed on the lower contact layer 122 constituting the bottom face of the groove 32. An interconnect 42 connected to a p electrode pad 43 is disposed on the p electrode 41 at the top of the mesa 30. An interconnect 52 connected to an n electrode pad 53 is disposed on the n electrode 51 situated on the bottom face of the groove 32.

The p electrode 41 is made of gold-zinc (AuZn) or the like, and has a thickness of approximately 150 nanometers, for example. The n electrode 51 is made of a film in which gold (Au), germanium (Ge), and nickel (Ni) are laminated, for example, and has a thickness of approximately 200 nanometers, for example. The interconnect 42, the interconnect 52, the p electrode pad 43, the n electrode pad 53, the first dummy pad 161, and the second dummy pad 162 are made of a metal such as Au, for example.

In the surface emitting laser of the present embodiment, bonding wires (not shown) or the like are connected to the p electrode pad 43 and the n electrode pad 53 to inject current into the surface emitting laser. Light emitted by the active layer 124 upon the injection of current oscillates in the resonator constituted by the first lower DBR layer 121, the second lower DBR layer 123, and the upper DBR layer 125, and then comes out of the light transmitting window 31 as a laser beam in the Z1 direction indicated by a dashed-line arrow.

### Variation

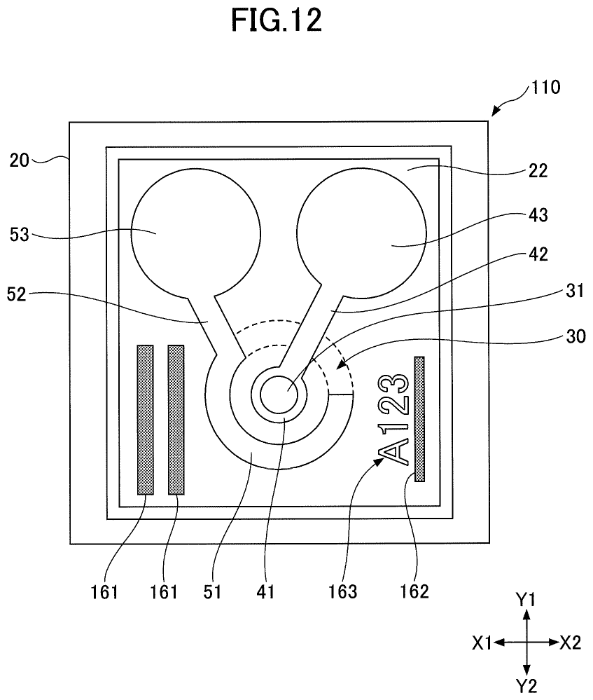

In the following, a variation of the surface emitting laser according to the present embodiment will be described. The surface emitting laser of the present embodiment may be such that a plurality of first dummy pads 161 are provided as illustrated in FIG. 12. In this case, the length of the first dummy pads 161 in the Y1-Y2 direction is preferably 80 micrometers or more and 100 micrometers or less, and the area in which the two first dummy pads 161 are provided is preferably in the range of micrometers to 40 micrometers in the X1-X2 direction.

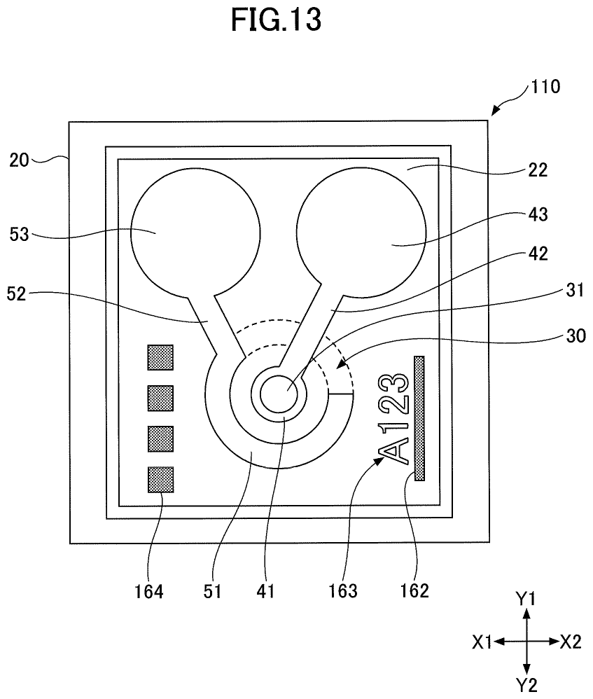

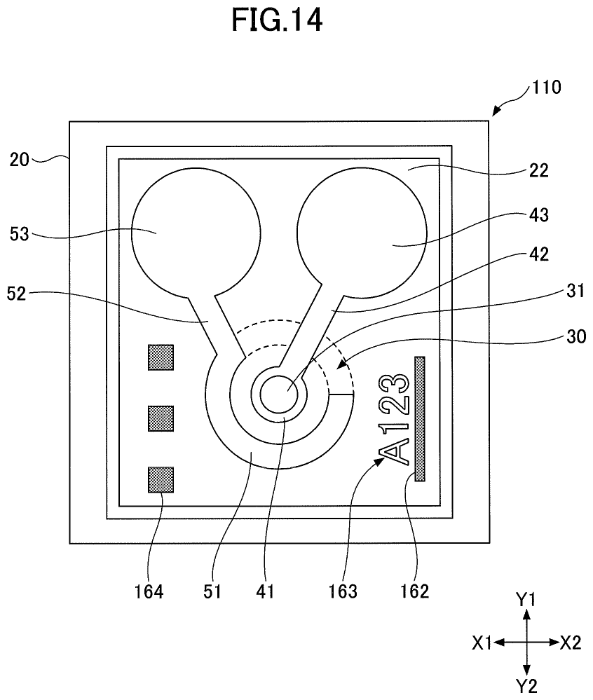

Further, the surface emitting laser of the present embodiment may be such that a plurality of first dummy pads 164 are aligned in the Y1-Y2 direction as illustrated in FIG. 13 and FIG. 14. Specifically, a plurality of first dummy pads 164 having a square shape with a side of 20 micrometers to 40 micrometers may be aligned in the Y1-Y2 direction. In this case, the spatial range in which the first dummy pads 164 are aligned in the Y1-Y2 direction is preferably greater than or equal to 80 micrometers and less than or equal to 100 micrometers. FIG. 13 illustrates the case in which four first dummy pads 164 are aligned in the Y1-Y2 direction. FIG. 14 illustrates the case in which three first dummy pads 164 are aligned in the Y1-Y2 direction.

Although one or more embodiments have heretofore been described, any particular embodiments are non-limiting, and various variations and modifications may be made without departing from the scopes defined by the claims.

The present application is based on and claims priority to Japanese patent application No. 2019-122050 filed on Jun. 28, 2019, with the Japanese Patent Office, the entire contents of which are hereby incorporated by reference.

What is claimed is

1. A surface emitting laser, comprising:
a substrate;
semiconductor layers including a lower contact layer, a lower reflector layer, an active layer, an upper reflector layer, and an upper contact layer which are laminated, in the order named, on the substrate;
a light transmitting window configured to transmit laser light from the semiconductor layers;
a first electrode pad connected to the upper contact layer;
a second electrode pad connected to the lower contact layer;
a first dummy pad; and
a second dummy pad,
wherein the first electrode pad, the second electrode pad, the first dummy pad, and the second dummy pad are disposed on the semiconductor layers at a place different from the light transmitting window, and
wherein the substrate is classified into a first region, a second region, a third region, and a fourth region by both a straight line extending in a first direction passing through a center of the substrate in a plan view and a straight line extending in a second direction perpendicular to the first direction and passing through the center of the substrate,
the first electrode pad being situated in the first region,
the second electrode pad being situated in the second region,
the first dummy pad being situated in the third region, and
the second dummy pad being situated in the fourth region.

2. A surface emitting laser, comprising:
a substrate;
semiconductor layers including a lower contact layer, a lower reflector layer, an active layer, an upper reflector layer, and an upper contact layer which are laminated, in the order named, on the substrate;
a light transmitting window configured to transmit laser light from the semiconductor layers;
a first electrode pad connected to the upper contact layer;
a second electrode pad connected to the lower contact layer;
a first dummy pad; and
a second dummy pad,
wherein the first electrode pad, the second electrode pad, the first dummy pad, and the second dummy pad are disposed on the semiconductor layers at a place different from the light transmitting window, and
wherein the light transmitting window is situated between the first dummy pad and the second dummy pad.

3. The surface emitting laser as claimed in claim 1, wherein the first dummy pad and the second dummy pad are an oblong rectangular shape,
wherein a length of a short side of the oblong rectangular shape is greater than or equal to micrometers and smaller than or equal to 40 micrometers, and
wherein a length of a long side of the oblong rectangular shape is greater than or equal to micrometers and smaller than or equal to 100 micrometers.

4. The surface emitting laser as claimed in claim 1, wherein a plurality of said first dummy pads are provided,
wherein a length of each of the first dummy pads in the first direction ranges from 20 micrometers to 40 micrometers, and
wherein the plurality of first dummy pads are aligned in the second direction perpendicular to the first direction.

5. The surface emitting laser as claimed in claim 1, wherein a distance from an edge of the substrate to an edge of the first dummy pad that is closest to the edge of the substrate is greater than or equal to 20 micrometers and less than or equal to 50 micrometers.

6. The surface emitting laser as claimed in claim 2, wherein the first dummy pad and the second dummy pad are an oblong rectangular shape,
wherein a length of a short side of the oblong rectangular shape is greater than or equal to 5 micrometers and smaller than or equal to 40 micrometers, and
wherein a length of a long side of the oblong rectangular shape is greater than or equal to 80 micrometers and smaller than or equal to 100 micrometers.

7. The surface emitting laser as claimed in claim 2, wherein a plurality of said first dummy pads are provided,
wherein a length of each of the first dummy pads in a first direction ranges from 20 micrometers to 40 micrometers, and
wherein the plurality of first dummy pads are aligned in a second direction perpendicular to the first direction.

8. The surface emitting laser as claimed in claim 2, wherein a distance from an edge of the substrate to an edge of the first dummy pad that is closest to the edge of the substrate is greater than or equal to 20 micrometers and less than or equal to 50 micrometers.
